(19) United States
(12) Patent Application Publication
(10) Pub. No.: US 2026/0275541 A1
(43) Pub. Date: Sep. 17, 2026

(54) An apparatus for simultaneous electrochemical processing of a plurality of electrodes

(71) Applicant: Teknologian tutkimuskeskus VTT Oy, Espoo (FI)

(72) Inventors: Liam Gillan, Espoo (FI); Tuomas Happonen, Espoo (FI); Jussi Hiltunen, Espoo (FI)

(21) Appl. No.: 19/167,405

(22) PCT Filed: Mar. 6, 2024
(86) PCT No.: PCT/FI2024/050093

§ 371 Date: Sep. 22, 2025

(30) Foreign Application Priority Data
Mar. 20, 2023 (FI) 20235319

(51) Int. Cl. C25B 11/02; C25B 15/02; G01N 27/30

(52) U.S. Cl. CPC C25B 11/02; C25B 15/02; G01N 27/30

(57) ABSTRACT

There is provided an apparatus for simultaneous electrochemical processing of a plurality of electrodes, the apparatus comprising: a control unit; a fixture comprising a plurality of electrical contact pins connected to the control unit; and wherein the control unit is configured to:—control movement of the fixture to enable positioning of the plurality of electrical contact pins simultaneously into contact with the plurality of electrodes; and/or-control movement of the plurality of electrodes to enable positioning of the plurality of electrodes into contact with the plurality of electrical contact pins; and perform electrochemical processing simultaneously on the plurality of electrodes via the electrical contact pins.

### FIELD

Various example embodiments relate to an apparatus for simultaneous electrochemical processing of a plurality of electrodes, and a method for performing electrochemical processing on a plurality of electrodes simultaneously.

### BACKGROUND

Electrochemical sensors requiring electrochemical processing are typically fabricated individually. Individual processing is labor-intensive and as such not suitable for producing high unit volumes of electrochemical sensors.

### SUMMARY

According to some aspects, there is provided the subject-matter of the independent claims. Some example embodiments are defined in the dependent claims. The scope of protection sought for various example embodiments is set out by the independent claims. The example embodiments and features, if any, described in this specification that do not fall under the scope of the independent claims are to be interpreted as examples useful for understanding various example embodiments.

According to a first aspect, there is provided an apparatus for simultaneous electrochemical processing of a plurality of electrodes, the apparatus comprising: a control unit; a fixture comprising a plurality of electrical contact pins connected to the control unit; and wherein the control unit is configured to:-move the fixture to enable positioning of the plurality of electrical contact pins simultaneously into contact with the plurality of electrodes; and/or-move the plurality of electrodes to enable positioning of the plurality of electrodes into contact with the plurality of electrical contact pins; and perform electrochemical processing simultaneously on the plurality of electrodes via the electrical contact pins.

According to an embodiment, the electrical contact pins are spring probe electrical contact pins.

According to an embodiment, the electrochemical processing comprises voltammetry and/or amperometry to perform electromodification of the plurality of electrodes.

According to an embodiment, the plurality of electrical contact pins are arranged in an array pattern.

According to a second aspect, there is provided a method for performing electrochemical processing on a plurality of electrodes simultaneously using the apparatus of any preceding claim, the method comprising: providing a first set of the plurality of electrodes to a first position below the fixture; arranging the plurality of electrical contact pins into contact with the first set of the plurality of electrodes; and performing electrochemical processing simultaneously on the first set of the plurality of electrodes via the plurality of electrical contact pins.

According to an embodiment, the method comprises: moving the first set of the plurality of electrodes away from the first position; providing a second set of a plurality of electrodes to the first position below the fixture; arranging the plurality of electrical contact pins into contact with the second set of the plurality of electrodes; and performing electrochemical processing simultaneously on the second set of the plurality of electrodes via the plurality of electrical contact pins.

According to an embodiment, the first set of the plurality of electrodes comprises electrodes on discrete sheets arranged on a carrier substrate.

According to an embodiment, the first set of the plurality of electrodes comprises electrodes on a roll arranged on a carrier substrate.

According to a third aspect, there is provided an apparatus for simultaneous electrochemical processing of a plurality of electrodes, the apparatus comprising: a fixture comprising a plurality of electrical contact pins; means for moving the fixture to enable positioning of the plurality of electrical contact pins simultaneously into contact with the plurality of electrodes; and/or means for moving the plurality of electrodes to enable positioning of the plurality of electrodes into contact with the plurality of electrical contact pins; and means for performing electrochemical processing simultaneously on the plurality of electrodes via the electrical contact pins.

### BRIEF DESCRIPTION OF THE DRAWINGS

Some example embodiments will now be described with reference to the accompanying drawings.

FIG. 1 shows, by way of example, an apparatus for electrochemical processing of electrodes;

FIG. 2 shows, by way of example, a side view of a fixture comprising a plurality of electrical contact pins;

FIG. 3 shows, by way of example, a bottom view of electrical contact pins in contact with electrodes of an electrochemical sensor;

FIG. 4 shows, by way of example, a flowchart of a method for performing electrochemical processing on a plurality of electrodes; and

FIG. 5 shows, by way of example, a manufacturing line of electrochemical sensor.

### DETAILED DESCRIPTION

Manufacturing of electrochemical sensors includes electrochemical processing, such as cyclic voltammetry and/or amperometry to perform electromodification of electrodes of the sensors. Typically, the sensors are fabricated individually or by sequential processing. When producing high volumes of sensors, fabricating the sensors individually may be inefficient.

An apparatus is provided, which enables simultaneous electrochemical processing of a plurality of electrodes or electrochemical sensors.

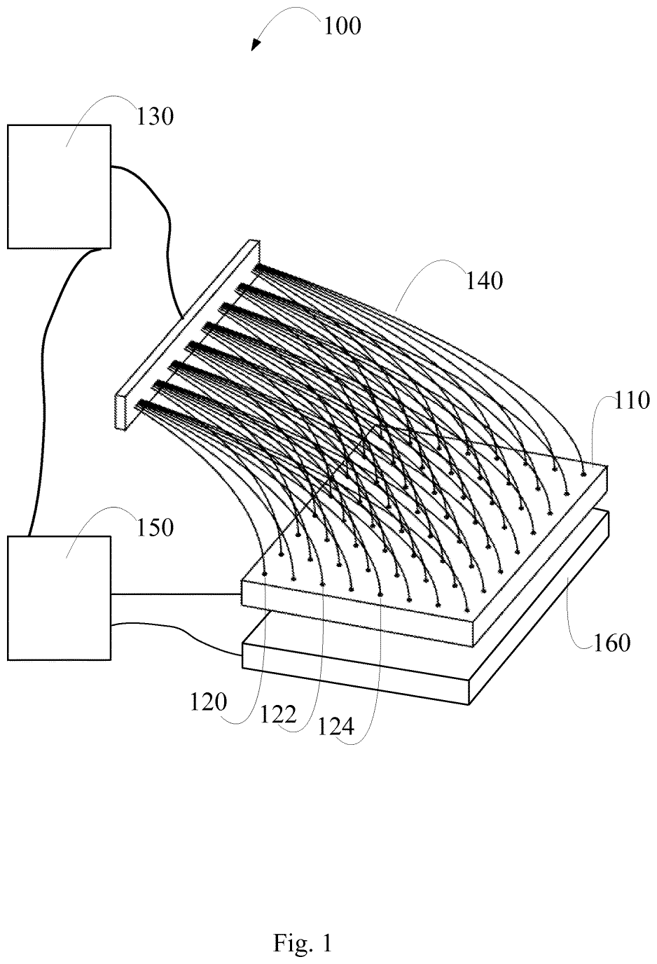

FIG. 1 shows, by way of example, an apparatus 100 for electrochemical processing of electrodes. An array of electrodes or sensors may be comprised on a carrier substrate 160. For example, the electrodes may be printed on a carrier substrate, or fabricated by other means, such as by evaporation through a shadow mask or by lithography. The carrier substrate may be, for example, a sheet or a roll comprising a plurality of sheets.

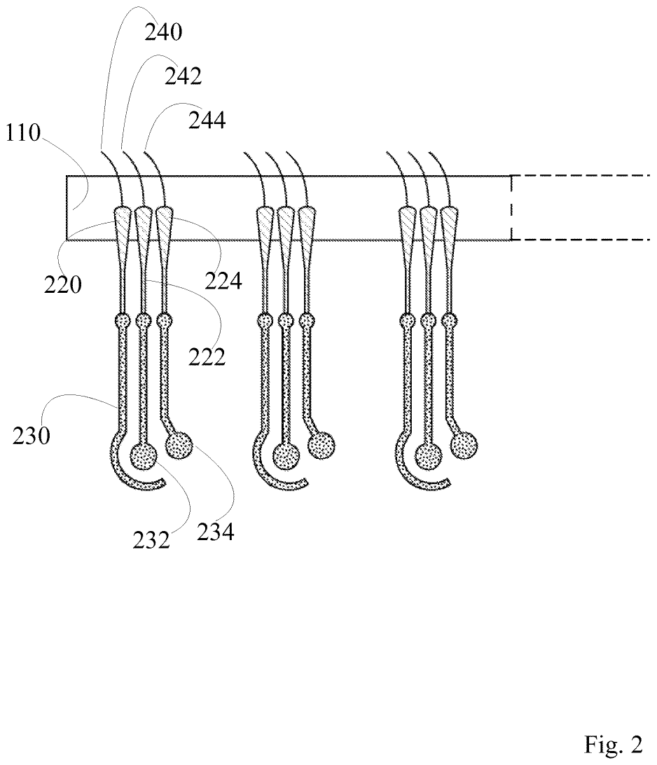

The apparatus 100 comprises a fixture 110 comprising a plurality of contact pins or electrical contact pins 120, 122, 124. The contact pins may be arranged partly inside the fixture 110 so that they penetrate the fixture. (see FIG. 2) The plurality of contact pins are connected to a control unit 130 via wires 140 (marked with a single reference number for simplicity).

The control unit 130 comprises controller electronics and is configured to, for example, perform electrochemical processing simultaneously on the electrodes via the contact pins. Individual electrodes may be coated with precursor mixture that can be activated by electrochemical processing. The control unit is capable of and configured to measure current while controlling voltage, and measure voltage while controlling current, for example.

The apparatus 100 comprises means for moving the fixture 110 to enable positioning of the plurality of electrical contact pins simultaneously into contact with the plurality of electrodes. For example, the apparatus 100 may comprise means for moving the fixture up so that the plurality of electrodes may be brought below the fixture; and down to position the fixture so that the plurality of contact pins 120, 122, 124 may be brought into contact simultaneously with a plurality of electrodes. The means may comprise, for example, motor(s) or actuator(s) 150 that may receive a control signal from the control unit 130. The control unit 130 may be configured to move the fixture 110 up and down by providing a control signal to the motor(s) or actuator(s) 150 for moving the fixture 110. The means for moving may comprise motor(s) or actuator(s) and a control unit configured to control the motor(s) or actuator(s).

The control unit 130 may be configured to move the fixture in other directions as well, depending how the manufacturing line of the electrodes or sensors is designed. The apparatus as disclosed herein enables processing in sheet-to-sheet and roll-to-roll manufacturing lines.

The carrier substrate comprising the electrodes may be arranged to move close to the fixture and stop below the fixture. The fixture may be moved down, or lowered, to bring the contact pins into contact with the electrodes.

After electrochemical processing, the fixture may be moved up, or lifted. The substrate may be arranged to move forward and a new batch of electrodes will be arranged below the fixture. This kind of manufacturing may be referred to as stop and go process.

As an alternative to moving the fixture up and down, the apparatus 100 may comprise means for moving the plurality of electrodes or the carrier substrate comprising the plurality of electrodes to enable positioning of the plurality of electrodes simultaneously into contact with the plurality of electrical contact pins. For example, the apparatus 100 may comprise means for moving the plurality of electrodes up and down, or moving the carrier substrate comprising the plurality of electrodes up and down. The means may comprise, for example, motor(s) or actuator(s) 150 that may receive a control signal from the control unit 130. The control unit 130 may be configured to move the plurality of electrodes or the carrier substrate comprising the plurality of electrodes up and down by providing a control signal to the motor(s) or actuator(s) 150 for moving the plurality of electrodes or the carrier substrate comprising the plurality of electrodes. The means for moving may comprise motor(s) or actuator(s) and a control unit configured to control the motor(s) or actuator(s).

The electrical contact pins may be spring probe pins. Spring probe pins enable contact with electrodes of varying height from the carrier substrate thereby enabling processing of electrodes having 3D morphology.

Layout of the electrical contact pins may be customized for matching different electrode layouts. For example, the electrical contact pins may be arranged in an array pattern.

Number of the electrical contact pins may be decided according to the design of the manufacturing line. Number of the pins is not limited but the fixture comprising the pins may be designed according to the manufacturing line. For example, the number of the pins may be several hundreds.

Material of the fixture may be, for example, fiberglass reinforced epoxy laminate or some other suitable rigid material.

FIG. 2 shows, by way of example, a side view of a fixture 110 comprising a plurality of electrical contact pins 220, 222, 224. Additionally, it is schematically shown how the contact pins are in contact with the electrodes 230, 232, 234. Contact pins are connected to the control unit via wires 240, 242, 244.

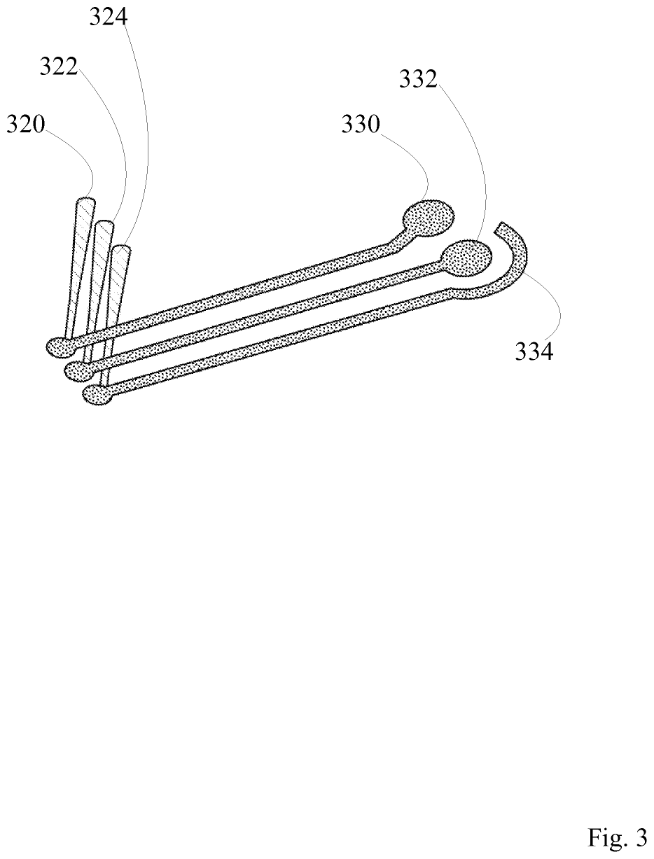

FIG. 3 shows, by way of example, a bottom view of electrical contact pins 320, 322, 324 in contact with electrodes 330, 332, 334 of an electrochemical sensor. In the example of FIG. 3, the sensor is a screen-printed sensor, and comprises a reference electrode (RE) 330, working electrode (WE) 332 and a counter electrode (CE) 334. The sensor comprises connecting lines for RE connection, WE connection and CE connection, respectively.

The electrochemical sensor may be, for example, printed on a sheet. The sheet may be a discrete sheet but the apparatus as disclosed herein may be used for electrochemical processing of electrodes on a roll as well.

The sensor may comprise more than three electrodes. For example, the sensor may comprise a plurality of working electrodes. The number of contact pins may be adjusted accordingly.

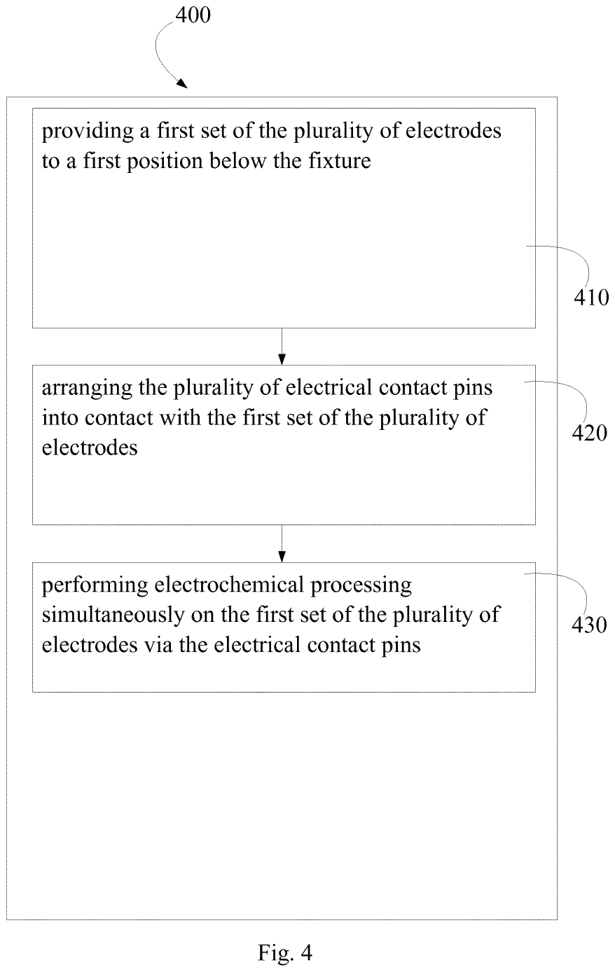

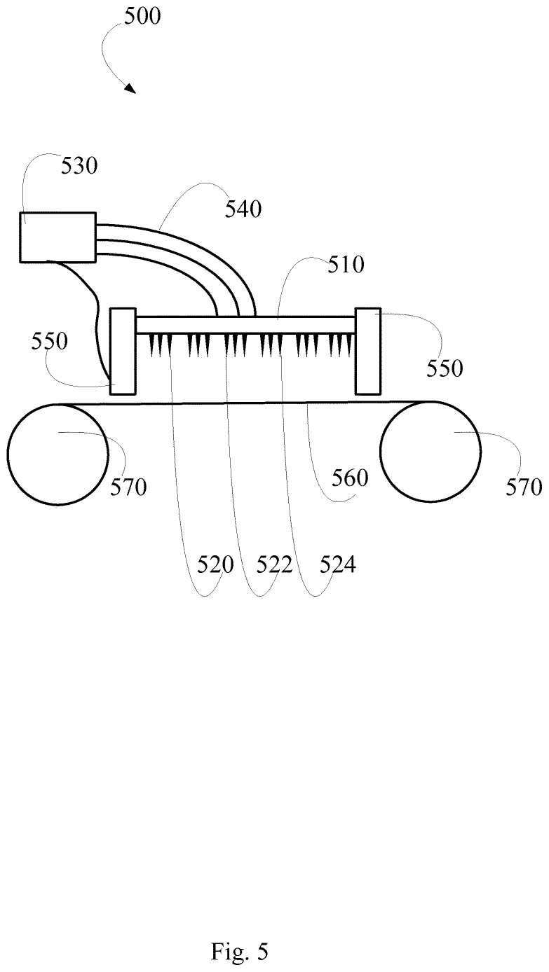

FIG. 4 shows, by way of example, a flowchart of a method 400 for performing electrochemical processing on a plurality of electrodes using the apparatus 100 of FIG. 1. The method may be performed in an automated manner, for example, by a manufacturing line of FIG. 5. Alternatively, some steps of the method may be performed by a human user. For example, electrodes on the carrier substrate may be provided to a first position below the fixture by a human user. As another example, electrodes may be moved away from the first position by a human user.

The method 400 comprises providing 410 a first set of the plurality of electrodes to a first position below the fixture. Provision of the electrodes on the carrier substrate may be performed automatically by a suitable machinery, or by a human user as described above.

The method 400 comprises arranging 420 the plurality of electrical contact pins into contact with the first set of the plurality of electrodes. Arranging into contact may be performed by moving the fixture or by moving the plurality of electrodes (or the carrier substrate comprising the electrodes). Moving of the fixture and the plurality of electrodes may be controlled by a control unit and actuators.

The method 400 comprises performing 430 electrochemical processing simultaneously on the first set of the plurality of electrodes via the electrical contact pins. Electrochemical processing may be controlled by a control unit. Electrochemical processing may comprise, for example, voltammetry and/or amperometry to perform electromodification of the electrodes. At least one chemical or precursor mixture may be added onto the electrode, or the chemical or precursor may be inherently part of the electrode (directly printed as an ink, for example), and electrochemical processing may be performed to electro-reduce or electro-oxidize the chemical or precursor. Means for performing electrochemical processing may comprise a control unit configured to perform electrochemical processing via the electrical contact pins connected to the control unit.

Following electrochemical activation, the electrodes may be washed to remove residual precursor mixture, and if desired, may be treated with further electrochemical process(es).

After processing the first set of electrodes, the fixture may be moved up by the control unit and the actuators. Alternatively, the electrodes may be lowered so that the contact pins are not anymore in contact with the electrodes. The first set of electrodes may be moved away from the first position. The first position is a position below the fixture.

A second set of a plurality of electrodes may be moved to the first position below the fixture.

The contact pins may be arranged into contact with the second set of electrodes.

Electrochemical processing may be performed simultaneously on the second set of electrodes via the electrical contact pins.

The electrodes may be arranged on discrete sheets arranged on a carrier substrate.

Alternatively, the electrodes may be arranged on a roll arranged on a carrier substrate. The roll may comprise a plurality of sheets.

Apparatus as disclosed herein enables reducing process duration compared to individual electrochemical processing of electrodes, thereby enabling high throughput fabrication. Apparatus as disclosed herein enables stop and go process, which is compatible with sheet-to-sheet and roll-to-roll mass manufacturing.

FIG. 5 shows, by way of example, a schematic drawing of a manufacturing line 500 of electrochemical sensors. The manufacturing line comprises the apparatus 100 of FIG. 1 for simultaneous electrochemical processing of a plurality of electrodes 560. The plurality of electrodes may be arranged on discrete sheets, for example so that electrodes of one sensor have been arranged on one sheet. Alternatively, the electrodes may be arranged on a roll. The electrodes may be arranged on a carrier substrate. The carrier substrate may comprise the plurality of electrodes, e.g. electrode arrays to be electro-processed.

Rolls 570 of electrodes or electrode arrays for positioning and storage of electrodes 560 may be arranged to move so that sets of electrodes may be provided or positioned below the fixture 510 comprising a plurality of electrical contact pins 520, 522, 524, and moved forward after the electrochemical processing.

The contact pins 520, 522, 524 are connected to the control unit 530 via wires 540.

The plurality of electrical contact pins 520, 522, 524 are arranged into contact with a first set of the plurality of electrodes. Arranging into contact may be performed, for example, by moving the fixture 510. The control unit 530 may be configured to move the fixture 510 using the mechanism 550 for raising or lowering the fixture 510. As another example, arranging into contact may be performed by moving the plurality of electrodes 560. The control unit 530 may be configured to move the plurality of electrodes 560 using a mechanism for raising or lowering the plurality of electrodes.

As a further example, both the fixture 510 and the plurality of electrodes 560 may be moved to enable the contact between the plurality of electrical contact pins and the plurality of electrodes. For example, the fixture 510 may be lowered and the plurality of electrodes may be raised.

Electrochemical processing may be simultaneously performed on the first set of the plurality of electrodes 560 via the electrical contact pins 520, 522, 524. The control unit may be configured to perform the electrochemical processing.

At least one chemical or precursor mixture may be added onto the electrode, or the chemical or precursor may be inherently part of the electrode (directly printed as an ink, for example). Electrochemical processing may be performed to electro-reduce or electro-oxidize the chemical or precursor. If the chemical or precursor mixture is added in the manufacturing line, an automated dispensing equipment may be comprised in the manufacturing line for adding the chemical or precursor mixture onto the electrodes.

After the first set of electrodes has been processed, the first set of electrodes is moved away from the first position, which is below the fixture 510.

A second set of a plurality of electrodes may be provided to the first position below the fixture 510. The plurality of electrical contact pins 520, 522, 524 are arranged into contact with the second set of the plurality of electrodes. Electrochemical processing may be simultaneously performed on the second set of the plurality of electrodes via the electrical contact pins.

After the second set of electrodes has been processed, the second set of electrodes is moved away from the first position and a following set of electrodes may be moved to the first position.

1. An apparatus for simultaneous electrochemical processing of a plurality of electrodes, the apparatus comprising:
a control unit;
a fixture comprising a plurality of electrical contact pins connected to the control unit; and wherein the control unit is configured to:
control movement of the fixture to enable positioning of the plurality of electrical contact pins simultaneously into contact with the plurality of electrodes; and/or
control movement of the plurality of electrodes to enable positioning of the plurality of electrodes into contact with the plurality of electrical contact pins; and
perform electrochemical processing simultaneously on the plurality of electrodes via the electrical contact pins.

2. The apparatus of claim 1, wherein the electrical contact pins are spring probe electrical contact pins.

3. The apparatus of claim 1, wherein the electrochemical processing comprises voltammetry and/or amperometry to perform electromodification of the plurality of electrodes.

4. The apparatus of claim 1, wherein the plurality of electrical contact pins are arranged in an array pattern.

5. A method for performing electrochemical processing on a plurality of electrodes simultaneously using the apparatus of any preceding claim, the method comprising:
providing a first set of the plurality of electrodes to a first position below the fixture;
arranging the plurality of electrical contact pins into contact with the first set of the plurality of electrodes; and
performing electrochemical processing simultaneously on the first set of the plurality of electrodes via the plurality of electrical contact pins.

6. The method of claim 5, further comprising:
moving the first set of the plurality of electrodes away from the first position;
providing a second set of a plurality of electrodes to the first position below the fixture;
arranging the plurality of electrical contact pins into contact with the second set of the plurality of electrodes; and
performing electrochemical processing simultaneously on the second set of the plurality of electrodes via the plurality of electrical contact pins.

7. The method of claim 5, wherein the first set of the plurality of electrodes comprises electrodes on discrete sheets arranged on a carrier substrate.

8. The method of claim 5, wherein the first set of the plurality of electrodes comprises electrodes on a roll arranged on a carrier substrate.

9. An apparatus for simultaneous electrochemical processing of a plurality of electrodes, the apparatus comprising:
a fixture comprising a plurality of electrical contact pins;
means for moving the fixture to enable positioning of the plurality of electrical contact pins simultaneously into contact with the plurality of electrodes; and/or
means for moving the plurality of electrodes to enable positioning of the plurality of electrodes into contact with the plurality of electrical contact pins; and
means for performing electrochemical processing simultaneously on the plurality of electrodes via the electrical contact pins.

10. The apparatus of claim 1, wherein the plurality of electrical contact pins are spring probe electrical contact pins arranged in an array pattern.

11. The apparatus of claim 1, wherein the plurality of electrical contact pins are spring probe electrical contact pins, and the electrochemical processing comprises voltammetry and/or amperometry to perform electromodification of the plurality of electrodes.

12. The apparatus of claim 1, wherein the plurality of electrical contact pins are arranged in an array pattern, and the electrochemical processing comprises voltammetry and/or amperometry to perform electromodification of the plurality of electrodes.

13. The apparatus of claim 1, wherein the plurality of electrical contact pins are spring probe electrical contact pins arranged in an array pattern, and the electrochemical processing comprises voltammetry and/or amperometry to perform electromodification of the plurality of electrodes.

14. The method of claim 5, further comprising:
moving the first set of the plurality of electrodes away from the first position;
providing a second set of a plurality of electrodes to the first position below the fixture;
arranging the plurality of electrical contact pins into contact with the second set of the plurality of electrodes; and
performing electrochemical processing simultaneously on the second set of the plurality of electrodes via the plurality of electrical contact pins,
wherein the first set of the plurality of electrodes comprises electrodes on discrete sheets arranged on a carrier substrate.

15. The method of claim 5, further comprising:
moving the first set of the plurality of electrodes away from the first position;
providing a second set of a plurality of electrodes to the first position below the fixture;
arranging the plurality of electrical contact pins into contact with the second set of the plurality of electrodes; and
performing electrochemical processing simultaneously on the second set of the plurality of electrodes via the plurality of electrical contact pins,
wherein the first set of the plurality of electrodes comprises electrodes on a roll arranged on a carrier substrate.
